(19) United States
(12) Patent Application Publication
(10) Pub. No.: US 2008/0062738 A1
(43) Pub. Date: Mar. 13, 2008

(54) STORAGE ELEMENT AND METHOD FOR OPERATING A STORAGE ELEMENT

(76) Inventors: Florian Schamberger, Bad Reichenhall (DE); Andreas Baenisch, Munich (DE)

Correspondence Address: PATTERSON & SHERIDAN, LLP;Gero McClellan / Qimonda, 3040 POST OAK BLVD.,, SUITE 1500, HOUSTON, TX, 77056, US

(21) Appl. No.: 11/530,435

(22) Filed: Sep. 8, 2006

(51) Int. Cl. G11C 17/00

(52) U.S. Cl. 365/96; 365/104

(57) ABSTRACT

Storage element for permanently storing information in a memory device. A coupling circuit is configured to couple a first and a second fuse in parallel with a programming line. A programming unit to control the coupling circuit depending on a common write data to successively couple the first and the second fuse via the programming line with a programming potential.

### BACKGROUND OF THE INVENTION

1. Field of the Invention

The present invention is related to integrated circuits having storage elements for permanently storing information. The present invention is further related to a method for operating such a storage element in an integrated circuit.

2. Description of the Related Art

Storage elements for permanently storing information in integrated circuits are used to store setting data and in case of a memory device to store repair data which effect a replacing of erroneous memory cells with redundant memory cells. It is known to use laser fuse elements for storing such data which may be programmed by means of a laser fusing process. The laser fusing process can be applied only on bare dies as it requires free direct access to the surface of the integrated circuit.

To allow the usage of such storage elements even in packaged devices it has been recently known to integrate electrically programmable fuses, so called e-fuses, in the integrated circuit. E-fuses can be electrically programmed by applying a programming voltage. The reliability of electrical fuses, however, is reduced as the resistance in the programmed state of the electrical fuse varies widely and is further dependant on a read-out current used for reading the resistance state of the electrical fuse. During programming, the applied programming voltage usually breaks down as the resistance of the electrical fuse rapidly decreases. As a result, it may sometimes be that a programming voltage breaks down before the electrical fuse has been brought to a resistance which is sufficiently low to clearly assign a logical state thereto.

### SUMMARY OF THE INVENTION

According to a first aspect, a storage element for permanently storing information in a memory device is provided. The storage element comprises a first electrical fuse and a second electrical fuse; a coupling circuit to couple the first and the second fuse in parallel with a programming line; and a programming unit to control the coupling circuit depending on a common write data to successively couple the first and the second fuse via the programming line with a programming potential.

According to a further aspect, a storage element for permanently storing information in a memory device is provided. The storage element comprises a first fuse circuit including a first fuse coupled with a first controllable fuse switch; a second fuse circuit including a second fuse coupled with a second controllable fuse switch; a programming line coupled with both the first and the second fuse circuits so that the fuse circuits are connected in a parallel manner; a programming source to supply a programming voltage; a programming switch to couple the first and the second fuse circuit with the programming source; and a programming circuit which is coupled with the programming switch, the first controllable fuse switch, and the second controllable fuse switch. For writing a data value the programming circuit renders conductive the programming switch and the first fuse switch to blow the first fuse, and after finishing the blowing of the first fuse the first fuse switch is isolated and the second fuse switch is rendered conductive to blow the second fuse.

According to another aspect, a method for permanently storing information in a storage element in a memory device is provided. The storage element comprises a first fuse circuit including a first fuse coupled with a first controllable switch; a second fuse circuit including a second fuse coupled with a second controllable switch; a programming line coupled with both the first and the second fuse circuits so that the fuse circuits are connected in a parallel manner; a programming source to supply a programming voltage; a programming switch to couple the first and the second fuse circuit with the programming source. The method comprises the steps of rendering conductive the programming switch and the first fuse switch to blow the first fuse, and after finishing the blowing of the first fuse, the first fuse switch is isolated and the second fuse switch is rendered conductive to blow the second fuse.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a block diagram of a storage element according to a preferred embodiment of the present invention;

FIG. 2 shows the electrical fuse circuits as used in the storage element of FIG. 1;

FIG. 3 shows the signaling diagram of the control signals for the storage element of FIG. 1; and

FIG. 4 shows a signal-time-diagram indicating a signal timing of a programming of a storage element of FIG. 1.

### DETAILED DESCRIPTION OF THE PREFERRED EMBODIMENT

The present invention will now be described by way of examples referring to the accompanying drawings.

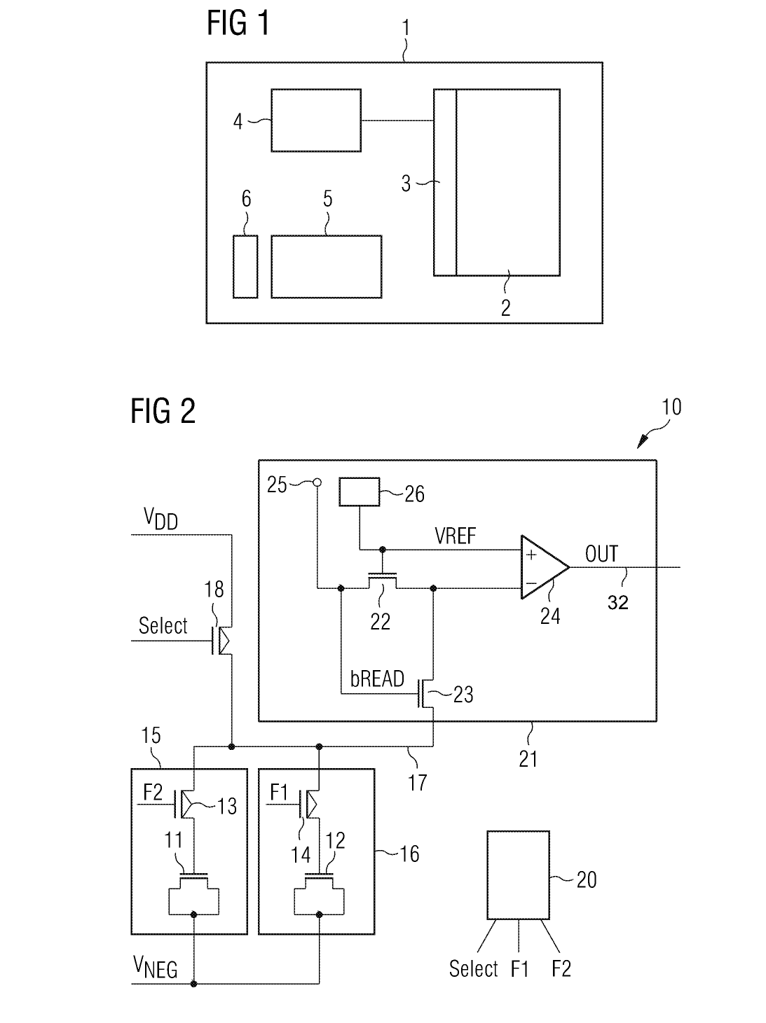

FIG. 1 shows one embodiment of an integrated memory circuit 1 having a memory cell array 2 in which memory cells (not shown) are arranged on word lines and bit lines (not shown). The memory cell array 2 has a redundancy portion 3 in which spare memory cells (not shown) are arranged to selectively replace memory cells from the memory cell array 2 in case it is detected as being erroneous. The operation of the integrated memory device 1 is controlled by a control circuit 4 the functions of which are commonly known in the art and therefore no further explanation is given herein. To indicate which memory cells in the memory cell array 2 are to be replaced by the spare memory cells repair information is permanently stored in storage elements of a repair unit 5. Additionally or optionally further storage elements for permanently storing setting data may be provided in a setting unit 6. Instead of a memory circuit any other integrated or electronic circuit may be provided with a setting unit having storage elements for permanently storing setting information.

One embodiment of a storage element according to the present invention is shown in FIG. 2. The storage element 10 of FIG. 2 comprises a first electrical fuse 11 and a second electrical fuse 12 which may be formed with a dielectric material in which an electrical conductive path can be formed. The electrical conductive path is formed by applying a programming voltage which leads to a breakthrough within the dielectric material. The electrical fuse may also be formed as a field effect transistor structure or commonly referred to as a MOS transistor structure having a gate oxide which is used as the dielectric material for the electrical fuse.

Each electrical fuse 11, 12 is connected in series with a respective field effect transistor 13, 14 for switching purposes which may be provided as a p-channel field effect transistor. In the present embodiment the field effect transistors 13, 14 are used as fuse switches and in the following they are referred to as the first and the second fuse switches 13, 14.

The first electrical fuse 11 and the first fuse switch 13 form a first fuse circuit 15 and the second fuse 12 and the second fuse switch 14 form a second fuse circuit 16. The first and the second fuse circuits 15, 16 are connected in parallel between a programming line 17 and a reference potential V_{NEG} which may a low supply potential, e.g. a ground potential for instance. The programming line 17 is coupled via a programming switch 18 with a programming potential V_{DD} which may be a high supply potential of the integrated circuit or the like.

A programming circuit 20 is provided to control the programming switch 18 (which may be formed as a p-type field effect transistor) by a select signal SELECT and to control the first and the second fuse switches 13,14 by means of a first and second control signal F1, F2 as discussed below. To fully open the fuse switches 13, 14 the programming circuit 20 may include level shifters to increase the potential of the first and second fuse signals so that the fuse transistors (p-type) can be fully opened controlled by the programming circuit 20.

A read unit 21 is provided which is coupled with the programming line 17 and which has an output 32 to output a logic level indicating the stored data of the storage element. The read unit 21 has a first read transistor 22 and a second read transistor 23 and an operational amplifier 24. Instead of an operational amplifier a comparator can be used. In detail, a non-inverting input of the operational amplifier 24 is supplied with a reference potential V_{REF} which indicates a threshold potential for discriminating the logic levels stored in the fuses 11, 12. The reference potential is supplied by a referential voltage source 26. The first read transistor 22 is connected with an activation port 25 by which a read-out of the storage element can be initiated by applying an activation signal. The activation port 25 is connected with a first terminal of the first read transistor 22. A second terminal of the first read transistor 22 is connected with the inverting input of the operational amplifier 24. A gate terminal of the first read transistor 22 is connected with the reference potential V_{REF}, i.e. with the non-inverting input of the operational amplifier 24. The output of the operational amplifier corresponds to the output of the read unit 21. A first terminal of the second read transistor 23 is coupled with the programming line 17 and a second terminal of the second read transistor 23 is coupled with the inverting input of the operational amplifier 24. A gate terminal of the second read transistor 23 is connected with the activation port 25.

The read unit 21 is controlled from externally by means of the activation signal. Depending on the activation signal the second read transistor 23 is closed and the information stored in the fuse circuits 15, 16 is read out. An output voltage level is output at the output of the operational amplifier 24 indicating the logic level of the stored logic state.

In the fuse circuits 15, 16 the logic state (information) is stored as a resistance of the electrical fuses 11, 12. To increase the reliability of storing information in the fuse circuit two fuse circuits 15, 16 are coupled in parallel to compensate for the case that one of the electrical fuses 11, 12 cannot be programmed to a resistance sufficiently low to clearly indicate the respective information. The programming of the electrical fuses 11, 12 is operated by the programming circuit 20 which provides the programming SELECT signal for the programming switch 18 as well as the first and second fuse signals F1, F2 for the first fuse switch and the second fuse switch, respectively.

Initially, i.e. immediately after production of the storage element, the electrical fuses 11, 12 are provided with a dielectric material in which no breakthrough path has been established such that the electrical resistances of such electrical fuses are initially high. In case that the first logic state is to be stored in the storage element the first and second electrical fuses remain unchanged, i.e. no programming voltage is applied to the electrical fuses to render their electrical resistances.

In case a second logic state is to be stored in the storage element the programming is performed as follows. The programming circuit 20 applies the programming signal SELECT to the gate terminal of the programming switch 18 such that the programming voltage V_{DD} is applied to the programming line 17. Moreover, the programming circuit 20 applies the first fuse signal F1 to a gate terminal of the first fuse switch 13 to render the first fuse switch 13 conductive. Thereby, the programming voltage of about V_{DD}-V_{NEG} is applied across the first fuse 11 such that programming occurs in which a breakthrough path is established in the dielectric material of the electrical fuse 11. As a result, the resistance of the electrical fuse decreases.

An example is now provided to illustrate how the reliability of storing information in the storage element of FIG. 1 can be enhanced. Assume that a first resistance state of the electrical fuses has a resistance of about 500 MegΩ and a second resistance state of the electrical fuses has a resistance of about 10 Meg Q. Furthermore, it is assumed that in a deteriorated electrical fuse the resistance of the second resistance state merely reaches 100 MegΩ. As a result because of the parallel connection of the two electrical fuses the overall resistance is lowered to 50 MegΩ even in case that both electrical fuses have deteriorated characteristics.

While still applying the programming signal SELECT at the programming switch 18 the first fuse switch 13 is rendered non-conductive and immediately thereafter a second fuse signal F2 is applied to the second fuse switch 14 such that the programming voltage V_{DD}-V_{NEG} is applied via the second electrical fuse 12 to render the resistance of the second electrical fuse 12 towards a lower resistance. The activating of the second fuse switch 14 (by means of the second fuse signal F2) can be performed immediately after the first fuse switch 13 has been opened or, alternatively, can be performed after a time period (retention time) in which the voltage generator for supplying the programming potential V_{DD} recovers. Thereafter, after the second fuse 14 has been programmed the second fuse switch 14 is opened. Furthermore, the programming signal SELECT switches and the programming switch 18 is opened and the programming has been terminated.

Usually, a plurality of storage elements is provided in the integrated memory circuit such that a programming signal is applied to the next storage element preferably immediately or after the retention time of the programming voltage generator. The overall resistance of both fuse circuits 15, 16 resulting from the parallel connection of the fuse circuits 15, 16 is lower than the resistance in a case wherein only one electrical fuse is used for storing the information. Even in case that one of the electrical fuses 11, 12 could not be programmed correctly in the programming processing the resistance of the respective other electrical fuse which has been programmed correctly is still low to clearly indicate the stored logic state such that the stored logic state can be read out by the read unit 21 in a secure manner. Thereby, the reliability of the storage element can be enhanced. Even in the event that both electrical fuses could not be correctly programmed until both resistance levels (ranges) set for a programmed condition has been reached the parallel connection of both fuse elements could provide a resistance level which then is sufficiently low to be correctly interpreted by the read unit 21.

Of course, more than two fuse circuits can be applied which are connected in parallel wherein a programming is performed by successively activating the respective fuse switch and programming the respective electrical fuse. The reading out is always performed by simultaneous activating of the fuse switches to allow the overall resistance to be a result of the parallel interconnection of the fuse circuits.

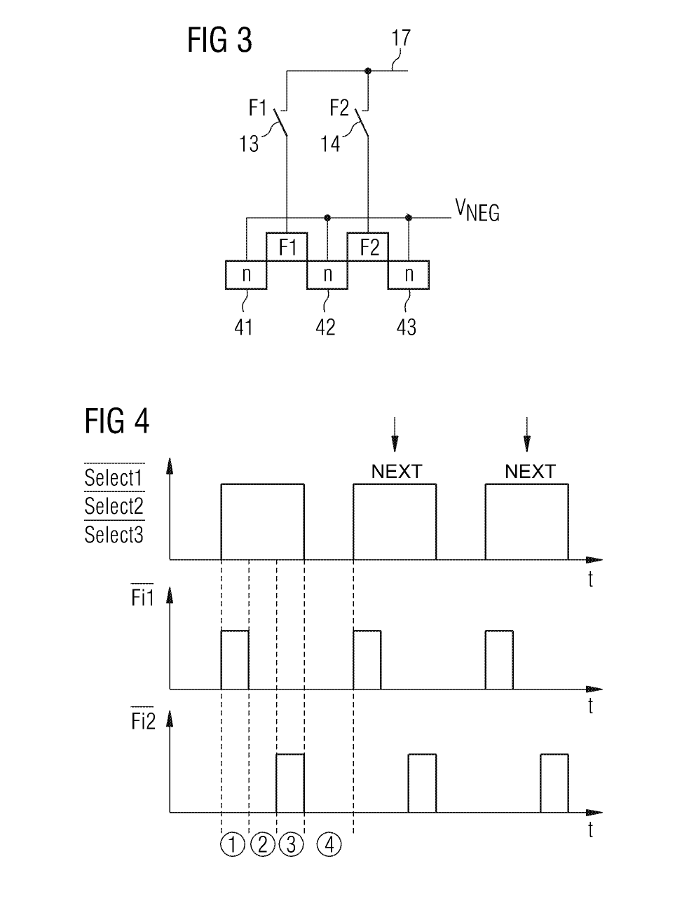

In FIG. 3 a schematic cross-sectional view of an integration of fuse elements is shown. As described above the fuse elements are implemented as transistor structures having doping areas 41, 42, 43 which may be formed in the same manner and in the same process steps as the source and drain regions of the switches and transistors further provided in the storage element. Between the first and the second doping region 41, 42 a gate oxide and a gate terminal is provided which is connected with the first fuse switch 13 and between the second and the third doping region 42, 43 a second gate oxide and a second gate terminal is provided which is connected with the second fuse switch 14. The doping regions 41, 42, 43 are short-cut and connected with the low supply potential V_{NEG}. The gate terminals are as indicated above connected via the fuse switches 13, 14 to the programming line 17.

In FIG. 4 a signal-time-diagram is shown indicating the programming signals SELECT1, SELECT2, SELECT3 for controlling a plurality of programming switches each provided for one storage element, and the fuse signals F1, F2 for controlling the first and second fuse switches 13, 14, respectively. It can be seen that while activating the respective programming switch of one storage element the first and the second fuse switch 13, 14 are successively closed while between the closing states a retention time is provided to allow the source for the programming potential to recover.

The proposed storage element provides an improved reliability for storing a logic state (programmed state, resistance lower than in initial state). The proposed storage element further provides an improved low temperature behavior.

While the foregoing is directed to embodiments of the present invention, other and further embodiments of the invention may be devised without departing from the basic scope thereof, and the scope thereof is determined by the claims that follow.

What is claimed is:

1. A storage element for storing information in a memory device; comprising:
a first electrical fuse and a second electrical fuse;
a coupling circuit to couple the first and the second fuse in parallel with a programming line; and
a programming unit to control the coupling circuit to successively couple the first and the second fuse via the programming line with a programming potential.

2. The storage element according to claim 1, wherein the first and the second fuse each have a first port and a second port, wherein the first ports are interconnected via a first line with a reference potential, wherein the coupling circuit comprising a first fuse switch a first node of which is coupled with the second port of the first fuse, and a second fuse switch a first node of which is coupled with the second port of the second fuse;
wherein the second nodes of the first and second fuse switches are commonly coupled with the programming line.

3. The storage element according to claim 2, further comprising a read unit coupled with the programming line and with the coupling circuit to control the first and the second fuse switches of the coupling circuit so that while reading from the storage element the first and the second fuse switches are closed to electrically connect the first and the second fuses with the programming line.

4. The storage element according to claim 3, wherein the read unit further comprises:
an operational amplifier having a non-inverting input and an inverting input;
a reference source coupled with the non-inverting input;
an activation port to receive an activation signal;
a first read transistor a first terminal of which is coupled with the activation port, a second terminal of which is coupled with the inverting input, and a gate terminal of which is coupled with the reference source; and
a second read transistor a first terminal of which is coupled with the programming line, a second terminal of which is coupled with the inverting input, and a gate terminal is connected with the activation port.

5. The storage element according to claim 1, wherein the first and the second fuses include a transistor structure in a substrate, wherein a gate insulator of the transistor structure is used as a fuse layer which may be made conductive by blowing the respective fuse.

6. A storage element for storing information in a memory device; comprising:
a first fuse circuit including a first fuse coupled with a first controllable fuse switch;
a second fuse circuit including a second fuse coupled with a second controllable fuse switch;
a programming line coupled with both the first and the second fuse circuits so that the fuse circuits are connected in a parallel manner;
a programming source to supply a programming voltage;
a programming switch to couple the first and the second fuse circuit with the programming source;
a programming circuit which is coupled with the programming switch, the first controllable fuse switch, and the second controllable fuse switch,
wherein for writing a data value the programming circuit closes the programming switch and the first fuse switch to blow the first fuse, and
wherein after finishing the blowing of the first fuse the first fuse switch is opened and the second fuse switch is closed to blow the second fuse.

7. A method for storing information in a storage element in a memory device, wherein the storage element comprises:
a first fuse circuit including a first fuse coupled with a first controllable switch;
a second fuse circuit including a second fuse coupled with a second controllable switch;
a programming line coupled with both the first and the second fuse circuits so that the fuse circuits are connected in a parallel manner;
a programming source to supply a programming voltage;
a programming switch to couple the first and the second fuse circuit with the programming source;
the method comprising:
closing the programming switch and the first fuse switch to blow the first fuse, and
after finishing the blowing of the first fuse, opening the first fuse switch and closing the second fuse switch, while the programming switch remains closed.

8. The method according to claim 7, wherein the first and the second fuse switches of the coupling circuit are controlled so that while reading from the storage element the first and the second fuse switches are made conductive to electrically connect the first and the second fuses with the programming line
